(19) United States
(12) Patent Application Publication
(10) Pub. No.: US 2010/0148148 A1
(43) Pub. Date: Jun. 17, 2010

(54) FABRICATION METHOD OF A LIGHT-EMITTING ELEMENT AND THE LIGHT-EMITTING ELEMENT

(76) Inventors: Shiuh CHAO, Hsinchu (TW); Chen-Yang Huang, Hsinchu (TW); Hao-Min Ku, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/371,144

(22) Filed: Feb. 13, 2009

(30) Foreign Application Priority Data
Dec. 11, 2008 (TW) 97148204

(51) Int. Cl. H01L 33/00; H01L 21/02; H01L 29/06

(52) U.S. Cl. 257/13; 438/29; 257/98; 257/E21.002; 257/E33.067; 257/E29.003

(57) ABSTRACT

A fabrication method of the light emitting element and its light emitting element are disclosed herein. It utilizes the membrane forming technology to form optic films arranged in array on a substrate and then upward forming the epitaxial layer by the epitaxial lateral overgrowth (ELOG) technology so as to form light-emitting elements in array. The optic films contribute to the high reflection property and can sustain high temperature in the ELOG process.

### BACKGROUND OF THE INVENTION

1. Field of the Invention

The present invention relates to an optical element, particularly to a fabrication method of a light-emitting element and the light-emitting element.

2. Description of the Related Art

Fabrication of a light-emitting diode array of prior art is shown in FIG. 1. Generally, an epitaxial layer of a light-emitting diode is formed on a substrate 100 by means of epitaxy, and a light-emitting element, as shown in FIG. 1, is formed after etching. This epitaxial layer of a light-emitting diode includes a P-type semiconductor layer 110, a quantum well active layer 120, and an N-type semiconductor layer 112 in order.

To increase the luminous efficiency of the light-emitting element, a common approach is to form on a substrate an optical layer of high refractive property to recycle backward scattered light rays, as disclosed in U.S. patent publication US20050133796A1. However, when the optical film layer is formed external to the light-emitting element, total internal reflection of LED light rays in the epitaxial layer can happen, causing the light rays not being able to reach outside the substrate; or multiple refractions losses from transmitting light rays of LED through the epitaxial layer and the substrate can occur before the light rays reach the external optical film layer. At this time, recycled and forward directed light rays, via reflection from the optical film layer, are very limited. Consequently, if the reflective optical film layer can be embedded into the epitaxial layer, i.e. arranging the reflective mirror in a location substantially close to the active light-emitting layer, the backward directed light rays can be reflected back in the epitaxial layer to avoid multiple refraction losses and the total reflection problem and thus forward luminous efficiency of LED is improved. However, the foregoing reflective mirror must sustain high temperature during epitaxy in order to be embedded in the epitaxial layer. Currently there is no prior art disclosing the fabrication method of a high temperature sustaining reflective mirror. To sum up the aforementioned descriptions, it is an important topic how to fabricate a light-emitting element of high luminous efficiency.

### SUMMARY OF THE INVENTION

In order to solve abovementioned problems, one objective of the present invention is to provide a fabrication method of a light-emitting element and the light-emitting element, by forming patterned optical films that can increase luminous efficiency and sustain high temperature during epitaxy.

One objective of the present invention is to provide a fabrication method of a light-emitting element and the light-emitting element by forming patterned optical film array directly on an epitaxial substrate and then fabricating light-emitting diode elements through epitaxy.

One embodiment of the present invention is to provide a fabrication method of a light-emitting element and the light-emitting element, wherein patterned optical film array can sustain high temperature during the epitaxy process.

In order to achieve aforementioned objectives, one embodiment of the present invention discloses a fabrication method of a light-emitting element including providing a substrate; forming a first optical layer on the substrate; removing a portion of the first optical layer to form a plurality of patterned first optical films, wherein the patterned first optical films are arranged in array on the substrate; forming a first semiconductor layer on the substrate and on the patterned first optical films in order via an epitaxial lateral overgrowth procedure, covering the substrate and the patterned first optical films; forming a light-emitting layer and a second semiconductor layer on the first semiconductor layer in order; and removing a portion of the first semiconductor layer, the light-emitting layer and the second semiconductor layer to form a plurality of patterned first semiconductor films, a plurality of patterned light-emitting films, and a plurality of second semiconductor films on the patterned first semiconductor films simultaneously.

Another embodiment of the present invention discloses a light-emitting element including a substrate; a plurality of patterned first optical films arranged in array on the substrate; a plurality of patterned first semiconductor films, arranged on the patterned first optical films; a plurality of patterned light-emitting films, arranged on the patterned first semiconductor films; and a plurality of patterned second semiconductor films, arranged on the patterned light-emitting films.

### BRIEF DESCRIPTION OF THE DRAWINGS

FIG. 1 is a diagram schematically showing a light-emitting element of prior art.

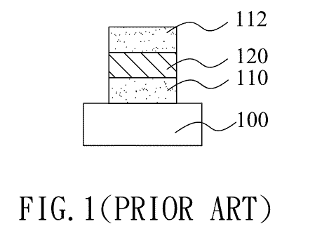

FIG. 2A-FIG. 2G are diagrams schematically showing one embodiment of the present invention.

FIG. 3 shows a schematic diagram of one embodiment of the present invention.

FIG. 4 shows a schematic diagram of one embodiment of the present invention.

FIG. 5A-FIG. 5I are diagrams schematically showing one embodiment of the present invention.

FIG. 6 shows a schematic diagram of one embodiment of the present invention.

FIG. 7 shows a schematic diagram of one embodiment of the present invention.

FIG. 8A, FIG. 8B and FIG. 8C are schematic diagrams showing different embodiments of the present invention, respectively.

FIG. 9 shows a schematic diagram of one embodiment of the present invention.

FIG. 10 shows a schematic diagram of one embodiment of the present invention.

### DETAILED DESCRIPTION OF THE INVENTION

The objectives, technical contents and characteristics of the present invention can be more fully understood by reading the following detailed description of the preferred embodiments, with reference made to the accompanying drawings.

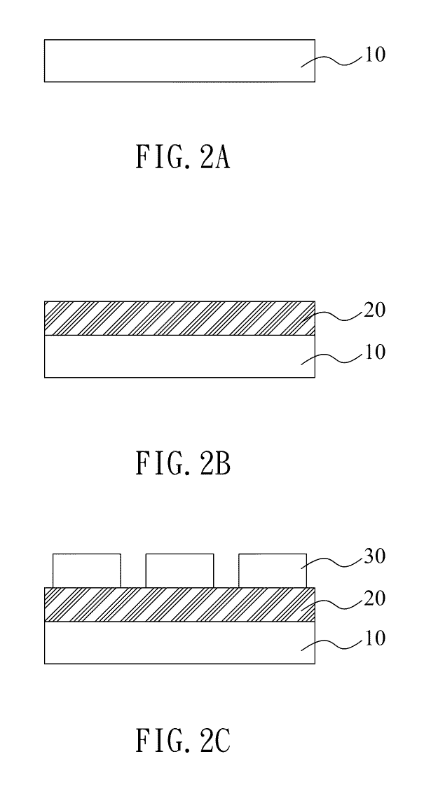

FIG. 2A, FIG. 2B, FIG. 2C, FIG. 2D, FIG. 2E, FIG. 2F and FIG. 2G constitute a flowchart of the fabrication method of a light-emitting element of one embodiment of the present invention. In this embodiment, the fabrication method of a light-emitting element comprises the following steps: first, a substrate 10 is provided, as shown in FIG. 2A. Next, please referring to FIG. 2B, FIG. 2C and FIG. 2D, a first optical layer 20 is formed on the substrate 10, and a portion of the first optical layer 20 is removed by patterning photoresist layer 30 via photomasking to form a plurality of patterned first optical films 20′ arranged in array on the substrate 10.

In continuation to the abovementioned description, as shown in FIG. 2E, a first semiconductor layer 40 is formed on the substrate 10 and on the patterned first optical films 20′ by an epitaxial lateral overgrowth procedure. The epitaxial lateral overgrowth procedure is conducted in a high temperature environment of a temperature above 900° C. Afterwards, a light-emitting layer 50 and a second semiconductor layer 42 are formed on the first semiconductor layer 40 in order, as shown in FIG. 2F. Then, please referring to FIG. 2G, a portion of the first semiconductor layer 40, light-emitting layer 50, and the second semiconductor layer 42 are removed to form a plurality of patterned first semiconductor films 40′, a plurality of patterned light-emitting films 50′, and a plurality of patterned second semiconductor films 42 simultaneously on patterned first optical films 20′.

In the abovementioned embodiment, the material of the substrate can be selected from the group consisting of sapphire, SiC, Si, GaAs, LiAlO₂, LiGaO₂, AlN or organic materials, etc. The first optical layer is a mutli-layer structure fabricated by sputtering, evaporation, chemical vapor deposition, chemical liquid deposition, chemical vapor epitaxy, or chemical liquid epitaxy. Epitaxial lateral overgrowth procedure can employ techniques such as molecular bean epitaxy (MBV), metal-organic chemical vapor deposition (MOCVD) or liquid phase epitaxy (LPE) and so on.

In one embodiment, the steps for removing a portion of the first optical layer 20 and removing a portion of the first semiconductor layer 40, light-emitting layer 50 and the second semiconductor layer 42 can be realized by lithography etching or laser drilling, etc.

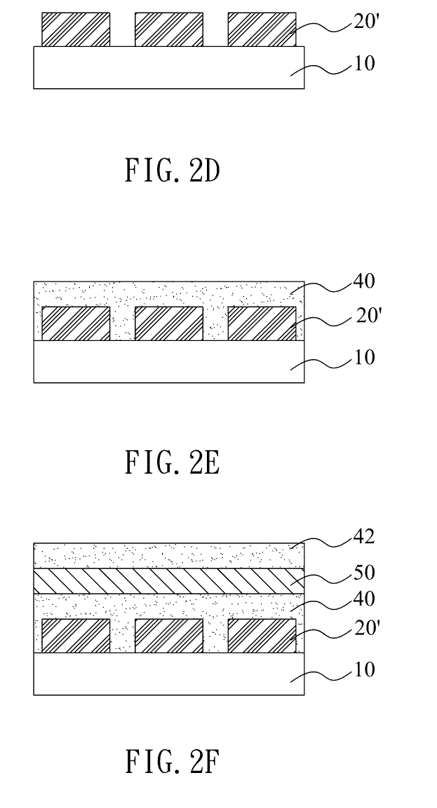

Please referring to FIG. 3, in one embodiment, the fabrication method of a light-emitting element further comprises forming a plurality of second optical films 22′ each of which on a portion of the surface of each patterned second semiconductor film 42′. Patterned second optical films 22′ can be fabricated by sputtering, evaporation, chemical vapor deposition, chemical liquid deposition, chemical vapor epitaxy, or chemical vapor epitaxy and so on. Besides, in one embodiment, fabrication method of a light-emitting element further comprises forming an electrode (60, 62) on the patterned first semiconductor films 40′ and the patterned second semiconductor films 42′.

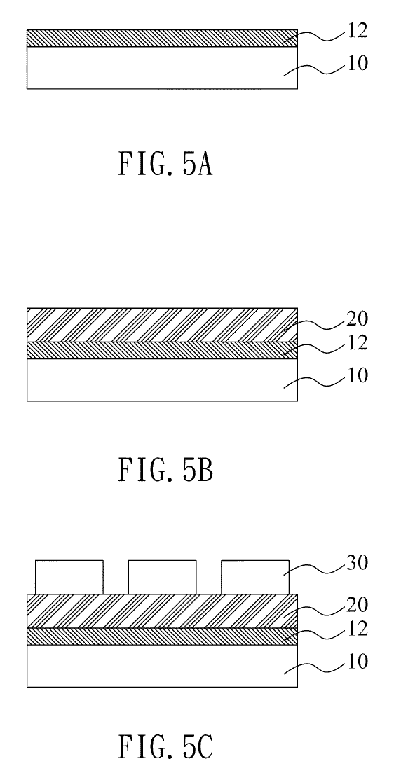

FIG. 5A, FIG. 5B, FIG. 5C, FIG. 5D, FIG. 5E, FIG. 5F, FIG. 5G, FIG. 5H and FIG. 5I constitute a flowchart of the fabrication method of a light-emitting element of another embodiment of the present invention. In the present embodiment, a substrate 10 contains a seed layer thereon, as shown in FIG. 5A. The seed layer 12 can be made of GaN. Then, as shown in FIG. 5B, FIG. 5C and FIG. 5D, a first optical layer 20 is formed on the substrate 10 and a patterned photoresist layer 30 is deposited for removing a portion of the first optical layer 20 via photomasking to form a plurality of first optical films 20′ arranged in array on the substrate 10. As shown in FIG. 5E, a first semiconductor layer 40, covering the substrate 10 and the patterned first optical films 20′, is formed by a procedure which applies epitaxial lateral overgrowth on the substrate 10 and the patterned first optical films 20′. Thereafter, a light-emitting layer 50 and a second semiconductor layer 42 are formed in order on the first semiconductor layer 40, as shown in FIG. 5F.

In continuation, please referring to FIG. 5G, the substrate 10 is removed with the seed layer 12 in contact with the patterned first optical films 20′ preserved, and a sub-substrate 10′ is set up under the seed layer 12. The substrate 10 can be recycled for reuse to effectively lower the cost. Low cost and better heat dissipating material can be selected for the sub-substrate 10′ according to needs.

Following the aforementioned description, a portion of the first semiconductor layer 40, light-emitting layer 50 and the second semiconductor layer 42 are removed to form a plurality of patterned first semiconductor films 40′, a plurality of patterned light-emitting films 50′ and a plurality of patterned second semiconductor films 42′ on the patterned first optical films 20′ simultaneously.

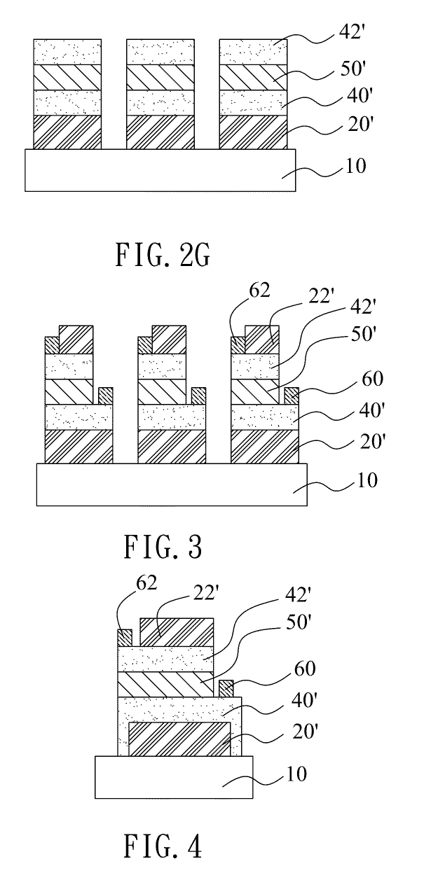

Please referring to FIG. 3 and FIG. 4, in this embodiment, a light emitting element is disclosed, which includes a substrate 10; a plurality of patterned first optical films 20′ arranged in array on the substrate 10; a plurality of patterned first semiconductor films 40′ arranged on the patterned first optical films 20′; a plurality of patterned light-emitting films 50′ arranged on the patterned first semiconductor films 40′; and a plurality of second semiconductor films 42′ arranged on the patterned light-emitting films 50′. In one embodiment, a plurality of patterned second optical films 22′ each of which is formed on a portion of the surface of each patterned second semiconductor film 42′. In one embodiment, an optical resonant cavity is formed between the patterned first optical films 20′ and the patterned second optical films 22′.

In one embodiment, the material of the first semiconductor films and the second semiconductor films can be semiconductor materials from group III-V or organic materials. In one embodiment, the first semiconductor films and the second semiconductor films are made of GaN or organic materials. In one embodiment, the patterned light-emitting films are PN junctions or quantum well structures.

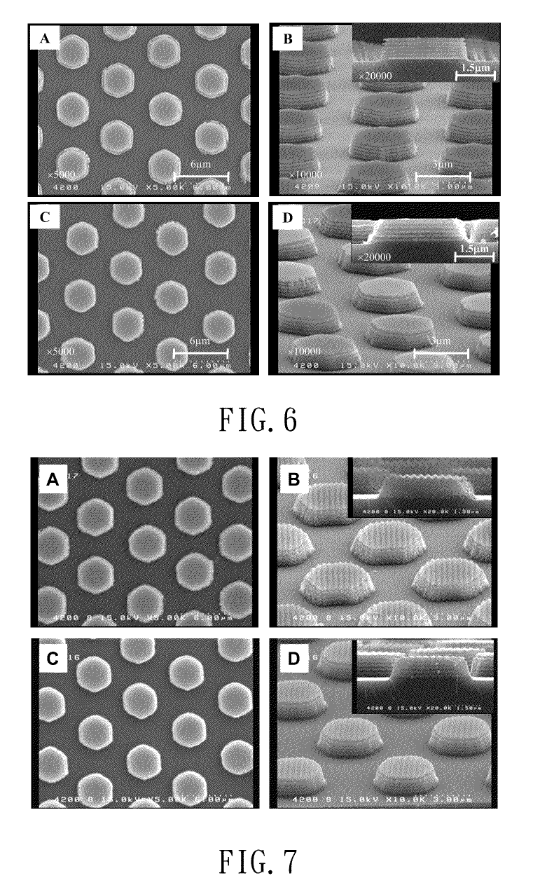

In continuation to the aforementioned description, in one embodiment, each of the patterned first optical films is a multi-layer structure which is composed of at least two materials of different refractive rate overlaying one another. The material of the multi-layer structure can be selected from the group consisting of TiO₂, Ta₂O₅, Nb₂O₅, CeO₂, ZnS, ZnO, SiO₂, MgF₂ and organic materials. In one embodiment, the multi-layer structure is a photonic crystal structure. In one embodiment, the multi-layer structure can be planar, saw-toothed, wavy, square-shaped or periodic as shown in FIG. 8A, FIG. 8B and FIG. 8C.

In one embodiment, the structure of the patterned second optical films 22′ is multi-layered, similar to that of the patterned first optical films 20′. Nevertheless, the patterned second optical films 22 can also be a non multi-layer structure. In one embodiment, the patterned second optical films can be a photonic crystal structure.

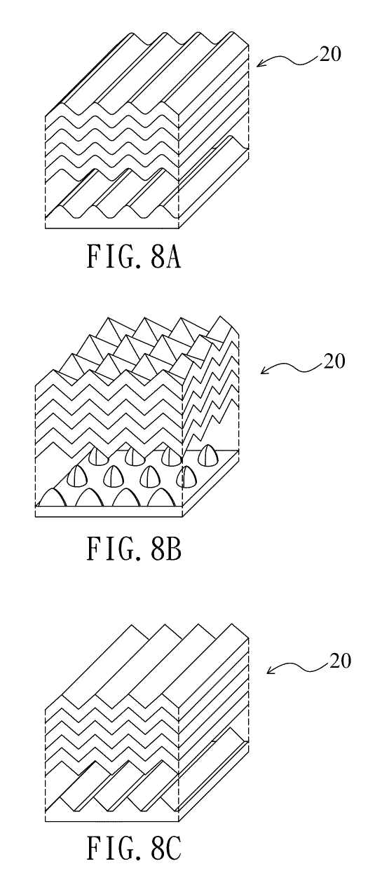

Please referring to FIG. 9, in different embodiments of the present invention, the shape of the patterned first optical films can be triangular, circular, square or polygonal. The patterned first optical films can be arranged in an array of a square shape, a triangular shape, or a polygonal shape.

According to the above descriptions, one characteristic of the present invention is to introduce an optical structure between each substrate and light-emitting structure. The optical structure makes each of the light-emitting unit of the semiconductor light-emitting element array to have a high reflective property. For a light-emitting diode array, the luminous efficiency is improved and for a semiconductor laser array, high reflective mirrors can be provided. In addition, the optical structures can sustain the high temperature during epitaxy, without deformation and peeling off.

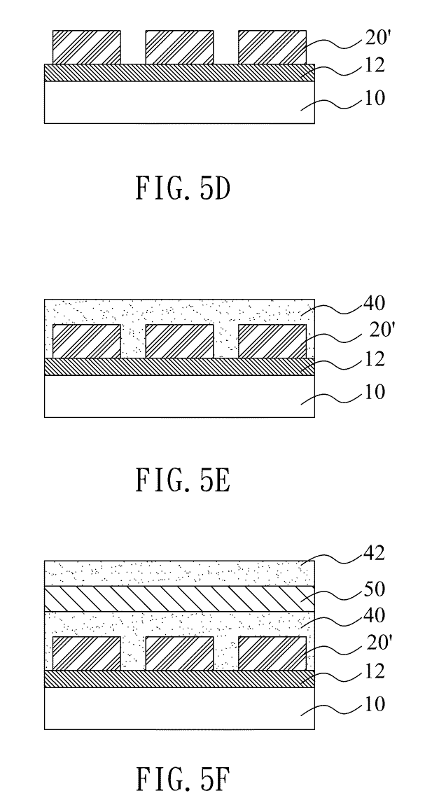

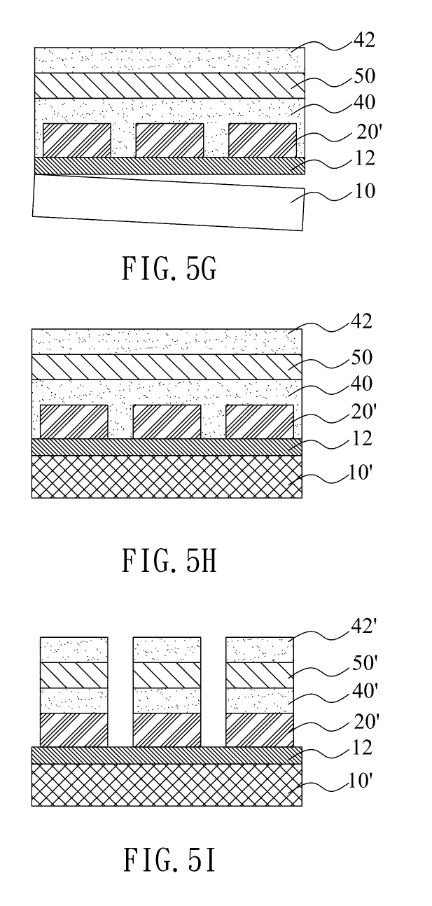

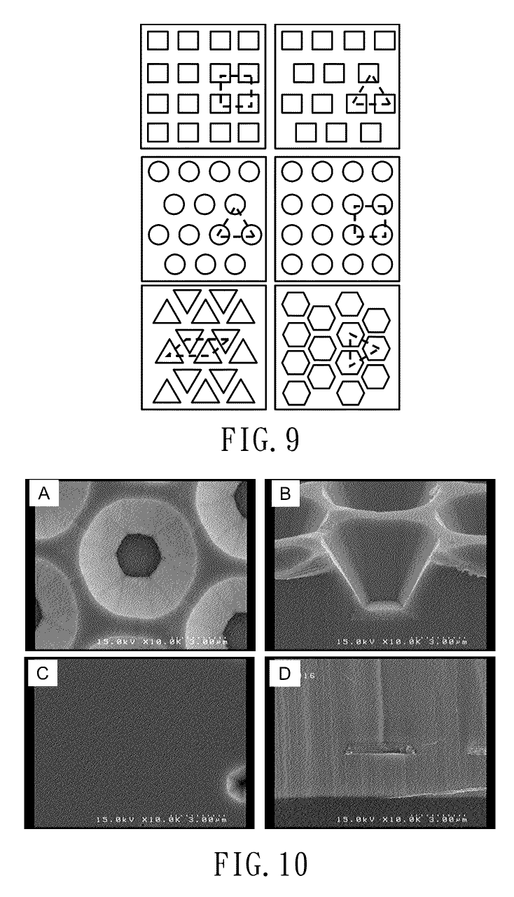

Please referring to FIG. 6A, FIG. 6B, FIG. 7A and FIG. 7B, the optical films of the present invention is placed in a quartz furnace tube to conduct a heating test which increases the temperature from room temperature to 1200□ in 30 minutes. Then the optical films are quickly cooled by fans and cycling water to room temperature in 60 minutes. From the experimental results shown in FIG. 6C, FIG. 6D, FIG. 7C and FIG. 7D, the optical films do not have any deformation, peel-off, fracture, or bulge and so on, a result which can prove the optical structure being able to sustain the high temperature during epitaxy of the semiconductor fabrication process. Moreover, please referring to FIG. 10, it shows the pictures of the optical films enduring the epitaxy process of the high temperature experiment. FIG. 10A and FIG. 10B show the vertical view and the cross-sectional view of the unfinished epitaxy process, respectively. As shown in FIG. 10A and FIG. 10B, in the epitaxy process, a semiconductor layer grows laterally until covering the optical films, and the optical films of the present invention do not show any deformation. Please continuingly referring to FIG. 10C and FIG. 10D, after the expitaxy process is completed, the semiconductor layer covers the optical films completely, and thus one can obviously know that there is no deformation, peel-off, fracture or bulge and so on during the high temperature epitaxy process.

In conclusion, the present invention discloses a fabrication method of patterned optical films which can increase luminous efficiency and sustain high temperature during epitaxy. The patterned optical film array is directly formed on the epitaxial substrate, and then the light-emitting diodes are formed by epitaxy. The patterned optical film array can sustain the high temperature during the epitaxy process. Each optical film and epitaxial layer of the present invention is not separately fabricated and then combined together, so the procedures can be reduced and the cost is effectively lowered. The technique of the present invention is not limited to the foregoing applications, and it also can be applied to organic light-emitting elements such as organic light-emitting diodes (OLED).

The embodiments described above are to demonstrate the technical contents and characteristics of the preset invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A fabrication method of a light-emitting element of which steps comprises:
providing a substrate;
forming a first optical layer on said substrate;
removing a portion of said first optical layer to form a plurality of patterned first optical films, wherein said patterned first optical films are arranged in array on said substrate;
forming a first semiconductor layer on said substrate and on said patterned first optical films in order via an epitaxial lateral overgrowth procedure, covering said substrate and said patterned first optical films;
forming a light-emitting layer and a second semiconductor layer on said first semiconductor layer in order; and
removing a portion of said first semiconductor layer, said light-emitting layer and said second semiconductor layer to form a plurality of patterned first semiconductor films, a plurality of patterned light-emitting films, and a plurality of second semiconductor films on said patterned first semiconductor films simultaneously.

2. The fabrication method of a light-emitting element according to claim 1, wherein said first optical layer is a multi-layer structure fabricated by sputtering, evaporation, chemical vapor deposition, chemical liquid deposition, chemical vapor epitaxy, or chemical liquid epitaxy, etc.

3. The fabrication method of a light-emitting element according to claim 1 further comprising forming a plurality of patterned second optical films each of which on a portion of the surface of each said patterned semiconductor film.

4. The fabrication method of a light-emitting element according to claim 3, wherein said patterned second optical film is fabricated by sputtering, evaporation, chemical vapor deposition, chemical liquid deposition, chemical vapor epitaxy, or chemical liquid epitaxy, etc.

5. The fabrication method of a light-emitting element according to claim 1, wherein said epitaxial lateral overgrowth procedure employs molecular beam epitaxy (MBE), metal-organic chemical vapor deposition (MOCVD) or liquid phase epitaxy (LPE) technique.

6. The fabrication method of a light-emitting element according to claim 1, wherein said substrate further comprises a seed layer on top.

7. The fabrication method of a light-emitting element according to claim 6 further comprising:
removing said substrate while preserving said seed layer in contact with said first optical layer; and
setting up a sub-substrate under said seed layer.

8. The fabrication method of a light-emitting element according to claim 1, wherein the step which removes a portion of said first optical layer or removes a portion of said first semiconductor layer, said light-emitting layer and said second semiconductor layer uses lithography etching or laser drilling, etc.

9. The fabrication method of a light-emitting element according to claim 1 further comprising forming an electrode on said patterned first semiconductor films and said patterned second semiconductor films respectively.

10. The fabrication method of a light-emitting element according to claim 1, wherein said epitaxial lateral overgrowth procedure is conducted in an environment of a high temperature above 900° C.

11. A light-emitting element comprising:
a substrate;
a plurality of patterned first optical films arranged in array on said substrate;
a plurality of patterned first semiconductor films, arranged on said patterned first optical films;
a plurality of patterned light-emitting films, arranged on said patterned first semiconductor films; and
a plurality of patterned second semiconductor films, arranged on said patterned light-emitting films.

12. The light-emitting element according to claim 11, wherein each said patterned first optical film is a multi-layer structure.

13. The light-emitting element according to claim 12, wherein said multi-layer structure is composed of at least two materials of different refractive rate overlaying one another.

14. The light-emitting element according to claim 12, wherein said multi-layer structure is a photonic crystal structure.

15. The light-emitting element according to claim 12, wherein said multi-layer structure is planar, saw-toothed, wavy, square-shaped, or periodic.

16. The light-emitting element according to claim 12, wherein the material of said multi-layer structure is selected from the group consisting of TiO₂, Ta₂O₅, Nb₂O₅, CeO₂, ZnS, ZnO, SiO₂, MgF₂ and organic materials.

17. The light-emitting element according to claim 11, further comprising a plurality of patterned second optical films each of which is arranged on a portion of the surface of each said patterned second semiconductor film.

18. The light-emitting element according to claim 17, wherein an optical resonant cavity is formed between said patterned first optic films and said patterned second optic films.

19. The light-emitting element according to claim 17, wherein said patterned second optical films are of a photonic crystal structure.

20. The light-emitting element according to claim 17, wherein said patterned second optical films are of a multi-layer structure.

21. The light-emitting element according to claim 11, wherein said substrate further comprises a seed layer on top.

22. The light-emitting element according to claim 11, wherein the material of said substrate is selected the group consisting of sapphire, SiC, Si, GaAs, LiAlO₂, LiGaO₂, AlN and organic materials.

23. The light-emitting element according to claim 11, wherein the shape of patterned first optical layers can be triangular, circular, square or polygonal.

24. The light-emitting element according to claim 11, wherein said patterned first optical films are arranged in array of a square shape, a triangular shape or a polygonal shape.

25. The light-emitting element according to claim 11, wherein the material of said first semiconductor layer and said second semiconductor layer is a semiconductor material from group III-V or an organic material.

26. The light-emitting element according to claim 11, wherein the material of the first semiconductor film and said second semiconductor film is selected from the group consisting of GaN, and organic materials.

27. The light-emitting semiconductor element further comprises a plurality of electrodes arranged on said patterned first semiconductor films and said patterned second semiconductor films.

28. The light-emitting element according to claim 11, wherein said patterned light-emitting films are PN junctions or quantum well structures.
